(19) United States
(12) Patent Application Publication
(10) Pub. No.: US 2026/0362743 A1
(43) Pub. Date: Nov. 12, 2026

(54) SEMICONDUCTOR DEVICE AND METHOD FOR FORMING THE SAME

(71) Applicant: TAIWAN SEMICONDUCTOR MANUFACTURING COMPANY LTD., HSINCHU (TW)

(72) Inventors: SUN-YI CHANG, NEW TAIPEI CITY (TW); TZU-HSIANG HSU, HSINCHU COUNTY (TW); PIN-CHENG HSU, HSINCHU COUNTY (TW); KATHERINE H. CHIANG, NEW TAIPEI CITY (TW); CHUNG-TE LIN, TAINAN CITY (TW)

(21) Appl. No.: 19/203,227

(22) Filed: May 9, 2025

(51) Int. Cl. H10D 30/67; H10D 30/01

(52) U.S. Cl. CPC H10D 30/6732; H10D 30/0316; H10D 30/6755

(57) ABSTRACT

A semiconductor device includes a gate structure, a channel layer over the gate structure, a gate dielectric layer between the gate structure and the channel layer, and a source structure and a drain structure over the gate dielectric layer. A height of the source structure is different from a height of the drain structure. The gate structure has a first surface facing the source structure and the drain structure, and a second surface opposite to the first surface. A width of the first surface is greater than a width of the second surface.

### BACKGROUND

Methods of forming transistors from oxide semiconductor (OS) materials represent an advancement in back-end-of-line (BEOL) integration in semiconductor manufacturing, due to low-temperature processing of such transistors. This feature is essential for preserving the integrity of devices fabricated in front-end-of-line (FEOL) and middle-end-of-line (MEOL) stages, allowing for the fabrication of transistors in a BEOL structure without risking damage to underlying structures. As the semiconductor industry aims to enhance areal density of integrated circuits, ongoing miniaturization of individual transistors is beginning to plateau. By moving the fabrication of the transistors from FEOL to BEOL stages, manufacturers can optimize chip area and introduce additional functionalities without compromising existing device layers. Therefore, integration of thin-film transistors in BEOL structures offers a strategic opportunity to improve device density while ensuring performance and reliability of semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of a semiconductor device according to aspects of the present disclosure in one or more embodiments.

FIG. 2 is a schematic cross-sectional view of a semiconductor device according to aspects of the present disclosure in one or more embodiments.

FIG. 3 is a schematic cross-sectional view of a semiconductor device according to aspects of the present disclosure in one or more embodiments.

FIG. 4 is a schematic cross-sectional view of a semiconductor structure including a plurality of semiconductor devices according to aspects of the present disclosure in one or more embodiments.

FIG. 5 is a flowchart representing a method for forming a semiconductor device according to aspects of the present disclosure.

FIGS. 6A-6G are schematic drawings of a semiconductor device at various fabrication stages constructed according to aspects of the present disclosure in one or more embodiments.

FIG. 7 is a flowchart representing a method for forming a semiconductor device according to aspects of the present disclosure.

FIGS. 8A-8G are schematic drawings of a semiconductor device at various fabrication stages constructed according to aspects of the present disclosure in one or more embodiments.

FIGS. 9A-9I are schematic drawings of a semiconductor structure at various fabrication stages constructed according to aspects of the present disclosure in one or more embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” "on" and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as "first," "second" and "third" describe various elements, components, regions, layers and/or sections, these elements, components, regions, layers and/or sections should not be limited by these terms. These terms may be only used to distinguish one element, component, region, layer or section from another. The terms such as "first," "second" and "third" when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms "substantially," "approximately" or “about” generally mean within a value or range that can be contemplated by people having ordinary skill in the art. Alternatively, the terms "substantially," "approximately" or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms "substantially," "approximately" or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure provides a semiconductor device and a method for forming the same. In some embodiments, the semiconductor device includes a gate structure having a funnel-shaped configuration that helps to increase gate-to-drain overlap. In other embodiments, the semiconductor device includes a drain structure having a footing configuration that helps to increase the gate-to-drain overlap. In still other embodiments, the semiconductor device includes both the funnel-shaped gate structure and the drain structure having the footing. It should be understood that the gate-to-drain overlap is related to a turn-on current and sub-threshold swing of a device. The increased gate-to-drain overlap improves gate control capability and induces an increased fringing field; thereby improving device performance. Further, a gate capacitance coupling is reduced.

While the present disclosure discusses aspects of methods of forming a semiconductor device in the context of a BEOL process or a subsequent MEOL process, such as a FinFET formation process in FEOL processes, other embodiments may utilize aspects of this disclosure with other semiconductor fabrication processes.

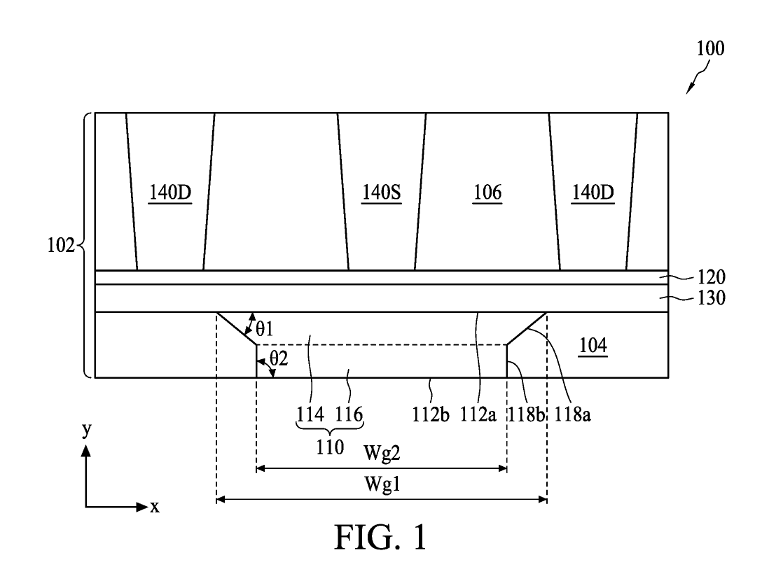

Please refer to FIGS. 1-3, each of FIGS. 1-3 is a schematic cross-sectional view of a semiconductor device 100, 100' or 100'' according to aspects of the present disclosure in one or more embodiments. Therefore, elements that are same in the embodiments shown in FIGS. 1-3 are depicted by same numerals. In some embodiments, elements that are same in the embodiments may have same parameters (e.g., depths or width), and may be formed by same materials, but the disclosure is not limited thereto.

In some embodiments, each of the semiconductor devices 100, 100' and 100'' may be formed over a substrate (not shown). In some embodiments, the substrate (not shown) may be any type of semiconductor body (including, for example, a semiconductor body formed of silicon (Si), silicon germanium (SiGe), silicon-on-insulator (SOI), or like), such as a semiconductor wafer and/or one or more dies on a wafer, as well as a semiconductor body formed of any other type of semiconductor and/or epitaxial layers, suitable for such application.

In some embodiments, the substrate can include FEOL devices and can be a portion of an IC chip, a system-on-chip (SoC), or a portion of a SoC. In some embodiments, the substrate can be a substrate accommodating FEOL devices such as microprocessors, memories, and/or other IC devices. In some embodiments, the substrate can include various passive and active microelectronic devices, such as resistors, capacitors, inductors, diodes, p-type field-effect transistors (PFETs), n-type field-effect transistors (NFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, other suitable components, or combinations thereof. The transistors may be planar transistors or multi-gate transistors, such as fin-type FETs (FinFETs).

In some embodiments, a layer of a MEOL interconnect structure (not shown) can be formed over the substrate. The layer of the MEOL interconnect structure includes a plurality of connecting vias (not shown) disposed in an inter-layer dielectric (ILD) layer (not shown). The connecting vias are coupled to the FEOL devices. In some embodiments, the connecting vias can include a via-to-gate (VG), which generally refers to contact with a gate structure. In other embodiments, the connecting via can include a via-to-drain (VD), which generally refers to contact with a source/drain region. Accordingly, the FEOL devices can be electrically connected to a BEOL interconnect structure through a layer of the MEOL interconnect structure.

In some embodiments, a BEOL interconnect structure 102 is formed over the substrate and is electrically connected to the FEOL devices over the substrate. In some embodiments, the BEOL interconnect structure 102 can include a plurality of metallization layers referred to, in ascending order, as the zeroth metallization layer M₀, the first metallization layer M₁, the (n-1)th metallization layer Mₙ₋₁, the Nth metallization layer Mₙ, and the (n+1)th metallization layer Mₙ₊₁, and a plurality of connecting vias referred to as the zeroth connecting via V₀, the first connecting via V₁, and the Nth connecting via Vₙ, wherein n is a positive integer. The (n-1)th metallization layer Mₙ₋₁ and the Nth metallization layer Mₙ can be electrically connected by the Nth connecting via Vₙ. Further, the metallization layer Mₙ and the connecting via Vₙ can be formed in an inter-metal dielectric layer IMDₙ, which provides mechanical support and electrical isolation for the metallization layers Mₙ and the connecting via Vₙ.

In some embodiments, each of the semiconductor devices 100, 100' and 100'' is disposed in the BEOL interconnect structure 102. For example but not limited thereto, the semiconductor device 100, 100' or 100'' is disposed in dielectric structures 104 and 106 over the Nth metallization layer Mₙ. In some embodiments, the semiconductor device 100, 100' or 100'' may be electrically connected to the Nth metallization layer Mₙ and/or the (n+1)th metallization layer Mₙ₊₁, but the disclosure is not limited thereto.

Each of the semiconductor devices 100, 100' and 100'' includes a gate structure 110 disposed in the dielectric structure 104. The gate structure 110 may include a conductive material. In some embodiments, the conductive material of the gate structure 110 may have a metal work function that is configured to increase a threshold voltage of the semiconductor device 100, 100' or 100'', thereby further mitigating a current flowing through a channel region. In some embodiments, the gate structure 110 may include platinum (Pt), titanium (Ti), titanium nitride (TiN), tantalum (Ta), tantalum nitride (TaN), tungsten (W), tungsten nitride (WN), copper (Cu), gold (Au), zinc (Zn), aluminum (Al), iron (Fe), nickel (Ni), beryllium (Be), chromium (Cr), cobalt (Co), antimony (Sb), iridium (Ir), molybdenum (Mo), osmium (Os), thorium (Th), vanadium (V), or a combination thereof. In some embodiments, the gate structure 110 may be referred to as a buried gate structure, but the disclosure is not limited thereto. In such embodiments, a top surface of the gate structure 110 may be aligned with or coplanar with a top surface of the dielectric structure 104, but the disclosure is not limited thereto.

Each of the semiconductor devices 100, 100' and 100'' includes a channel layer 120 disposed over the gate structure 110. In some embodiments, the channel layer 120 includes an oxide semiconductor material, (for example, but not limited to, indium gallium zinc oxide (InGaZnO, IGZO), tungsten-doped indium oxide (InWO), indium zinc oxide (InZnO), indium tin oxide (InSnO), indium tungsten oxide (InWO), gallium oxide (GaOx), indium oxide (InOx) or the like), doped zinc oxide, doped indium oxide, doped cadmium oxide, various other doped variants derived therefrom, amorphous silicon, crystalline silicon, or the like.

Each of the semiconductor devices 100, 100' and 100'' includes a gate dielectric layer 130 disposed between the channel layer 120 and the gate structure 110. The gate dielectric layer 130 may include any suitable dielectric material such as silicon oxide (SiO₂) or the like, or a high-k dielectric material such as silicon nitride (SiN₄), hafnium oxide (HfO₂), hafnium silicon oxide (HfSiO), hafnium tantalum oxide (HfTaO), hafnium titanium oxide (HfTiO), hafnium zirconium oxide (Hf_{0.5}Zr_{0.5}O₂), tantalum oxide (Ta₂O₅), aluminum oxide (Al₂O₃), hafnium dioxide-alumina (HfO₂—Al₂O₃), zirconium oxide (ZrO₂), or the like. Other suitable dielectric materials may also be within the contemplated scope of the disclosure.

Each of the semiconductor devices 100, 100' and 100'' further includes a source structure 140S and a drain structure 140D disposed over the gate structure 110 and the gate dielectric layer 130. The source structure 140S and the drain structure 140D are separated from each other. In some embodiments, each of the source structure 140S and the drain structure 140D includes platinum (Pt), ruthenium (Ru), palladium (Pd), tungsten (W), or gold (Au), but the disclosure is not limited thereto.

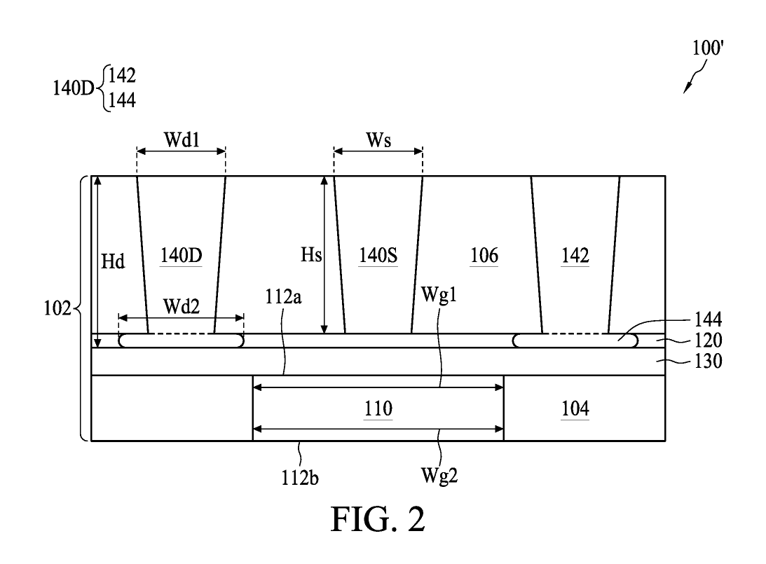

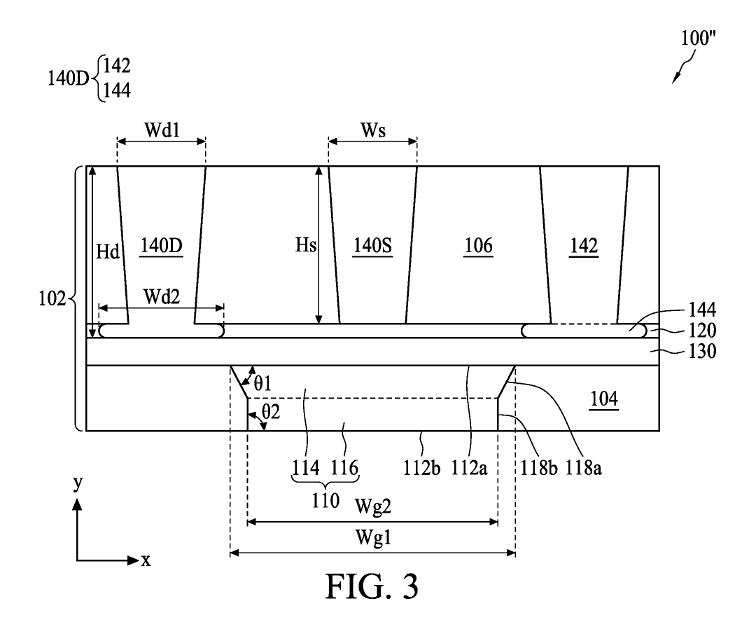

The gate structure 110 includes first surface 112a facing the source structure 140S and the drain structure 140D, and a second surface 112b opposite to the first surface 112a. In some embodiments, a width Wg1 of the first surface 112a is equal to a width Wg2 of the second surface 112b, in the cross-sectional view as shown in FIG. 2. In some alternative embodiments, the width Wg1 of the first surface 112a is different from the width Wg2 of the second surface 112b in the cross-sectional view. For example, the width Wg1 of the first surface 112a is greater than the width Wg2 of the second surface 112b, as shown in FIGS. 1 and 3. In such embodiments, the gate structure 110 may be said to have a first portion 114 and a second portion 116 under and coupled to the first portion 114. As shown in FIGS. 1 and 3, the first portion 114 has the first surface 112a, and the second portion 116 has the second surface 112b.

The first portion 114 has a first sidewall 118a with a first slope, and the second portion 116 has a second sidewall 118b with a second slope. The first slope and the second slope are defined as Δy/Δx. In some embodiments, the second slope is greater than the first slope.

Still referring to FIGS. 1 and 3, a first tangent angle θ1 is formed by the first sidewall 118a and the first surface 112a, and a second tangent angle θ2 is formed by the second sidewall 118b and the second surface 112b. In some embodiments, the first tangent angle θ1 is different from the second tangent angle θ2. In some embodiments, the first tangent angle θ1 is less than 90 degrees, and the second tangent angle θ2 is equal to or greater than 90 degrees. In some embodiments, the first tangent angle θ1 may be between approximately 60 degrees and approximately 75 degrees, but the disclosure is not limited thereto. In some embodiments, the second tangent angle θ2 may be between approximately 90 degrees and approximately 110 degrees, but the disclosure is not limited thereto.

Still referring to FIGS. 1 and 3, in some embodiments, the gate structure 110 including the first portion 114 and the second portion 116 may be said to have a funnel-shaped configuration. Further, the funnel-shaped configuration helps to increase gate-to-drain overlap or reduce a horizontal distance between the drain structure 140D and the gate structure 110.

In some embodiments, the source structure 140S and the drain structure 140D may have a same height, as shown in FIG. 1. The height of the source structure 140S may be defined as the measurement of a distance from a bottom surface of the source structure 140S to a top surface of the source structure 140S along the vertical axis. The height of the drain structure 140D may be defined as the measurement of a distance from a bottom surface of the drain structure 140D to a top surface of the drain structure 140D along the vertical axis. In such embodiments, both of the source structure 140S and the drain structure 140D are coupled to the channel layer 120. For example, a bottom of the source structure 140S and a bottom of the drain structure 140D are respectively in contact with the channel layer 120. Additionally, sidewalls of the source structure 140S and sidewalls of the drain structure 140D may be laterally surrounded by the dielectric structure 106 of the BEOL interconnect structure 102.

Referring to FIGS. 2 and 3, in some alternative embodiments, a height Hd of the drain structure 140D is different from a height Hs of the source structure 140S. For example, the height Hd of the drain structure 140D is greater than the height Hs of the source structure 140S. In such embodiments, the source structure 140S is coupled to the channel layer 120, while the drain structure 140D is coupled to the gate dielectric layer 130. For example, a bottom of the source structure 140S is coupled to or in contact with the channel layer 120, while a bottom of the drain structure 140D is coupled to or in contact with the gate dielectric layer 130. Further, in such embodiments, sidewalls of the source structure 140S are laterally surrounded by the dielectric structure 106 of the BEOL interconnect structure 106, while sidewalls of the drain structure 140D are in contact with both the dielectric structure 106 of the BEOL interconnect structure 102 and the channel layer 120.

Still referring to FIGS. 2 and 3, in some embodiments, the drain structure 140D includes a first portion 142 and a second portion 144 under and coupled to the first portion 142. In some embodiments, a width Wd1 is defined as a maximum width of the first portion 142, and a width Wd2 is defined as a maximum width of the second portion 144. In such embodiments, the width Wd1 of the first portion 142 is less than the width Wd2 of the second portion 144. Further, the width Wd2 of the second portion 144 of the drain structure 140D is greater than a width Ws (i.e., a maximum width) of the source structure 140S. In such embodiments, sidewalls of the first portion 142 of the drain structure 140D are laterally surrounded by the dielectric structure 106 of the BEOL interconnect structure 102, and sidewalls of the second portion 144 of the drain structure 140D are laterally surrounded by the channel layer 120.

Still referring to FIGS. 2 and 3, in some embodiments, the second portion 144 of the drain structure 140D may be referred to as a footing of the drain structure 140D. Further, the footing (i.e., the second portion 144) of the drain structure 140D helps to increase gate-to-drain overlap or reduce the horizontal distance between the drain structure 140D and the gate structure 110.

Referring to FIG. 3, it should be noted that the second portion 144 of the drain structure 140D and the first portion 114 of the gate structure 110 of the semiconductor device 100'' work together to further increase the gate-to-drain overlap. For example but not limited thereto, an overlap length may be between approximately 1 nanometer and approximately 5 nanometers.

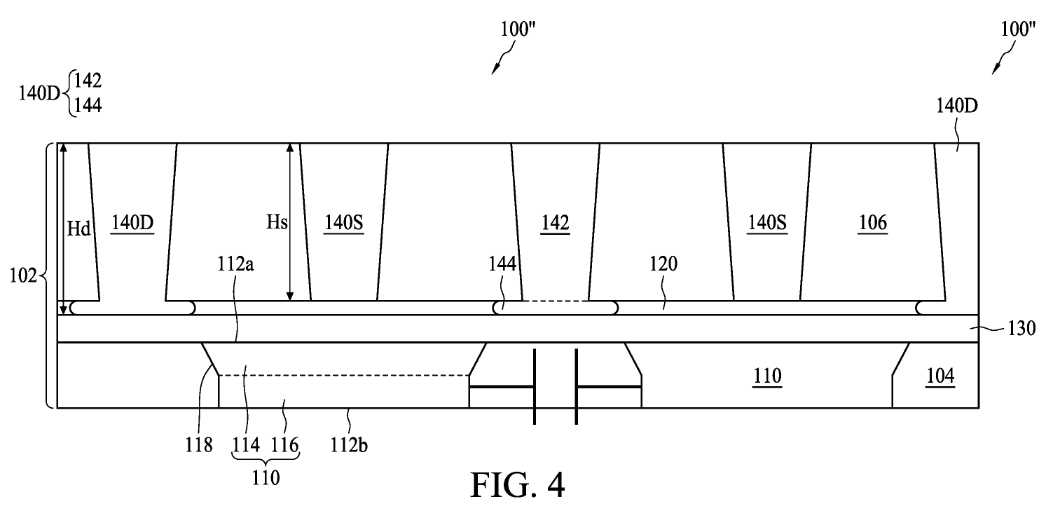

In some embodiments, the semiconductor device 100 may be periodically arranged. In other embodiments, the semiconductor device 100' may be periodically arranged. In other embodiments, the semiconductor device 100'' may be periodically arranged, as shown in FIG. 4, which illustrates a semiconductor structure including a plurality of semiconductor devices 100''. In such embodiments, two adjacent semiconductor devices 100'' may share a drain structure 140D disposed therebetween. Further, while the second portion 144 of the drain structure 140D and the first portion 114 of the gate structure 110 of each semiconductor device 100'' increase the gate-to-drain overlap, the second portions 116 of the gate structures 110 help to maintain a distance between adjacent gate structures 110 of adjacent semiconductor devices 100''. For example but not limited thereto, the distance between the adjacent gate structures 110 of the adjacent semiconductor devices 100'' may be between approximately 10 nanometers and approximately 50 nanometers. Accordingly, a gate capacitance between the adjacent gate structures 110 is reduced, and a gate coupling issue is mitigated by the funnel-shaped gate structures 110.

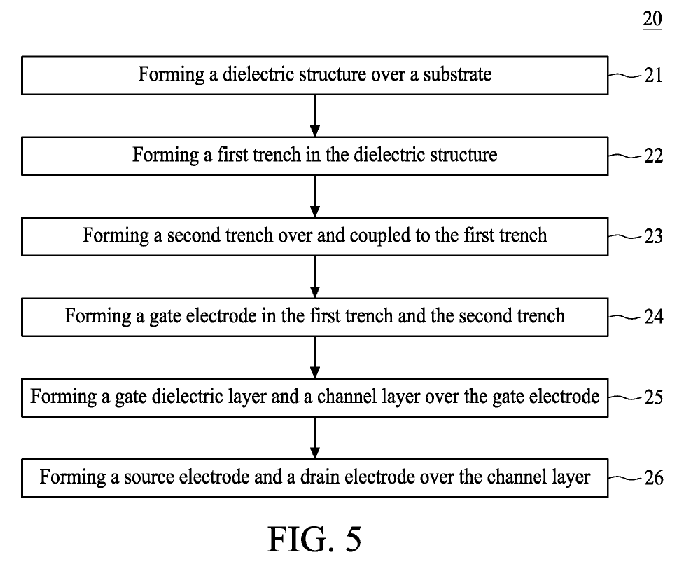

FIG. 5 is a flowchart representing a method for forming a semiconductor device 20 in accordance with aspects of the present disclosure. The method 20 includes a number of operations (21, 22, 23, 24, 25 and 26). The method 20 is further described according to one or more embodiments. It should be noted that the operations of the method 20 may be rearranged or otherwise modified within the scope of the various aspects. It should be further noted that additional processes may be provided before, during, and after the method 20, and that some other processes may be only briefly described herein. Thus, other implementations are possible within the scope of the various aspects described herein.

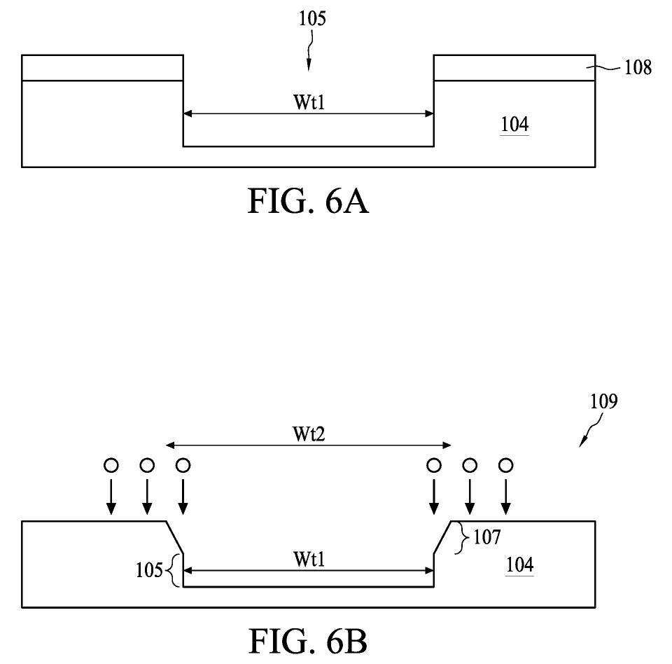

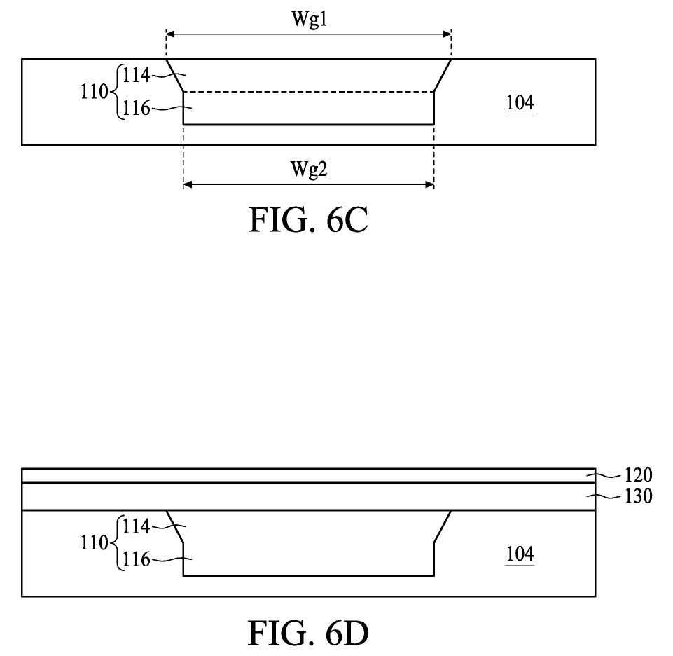

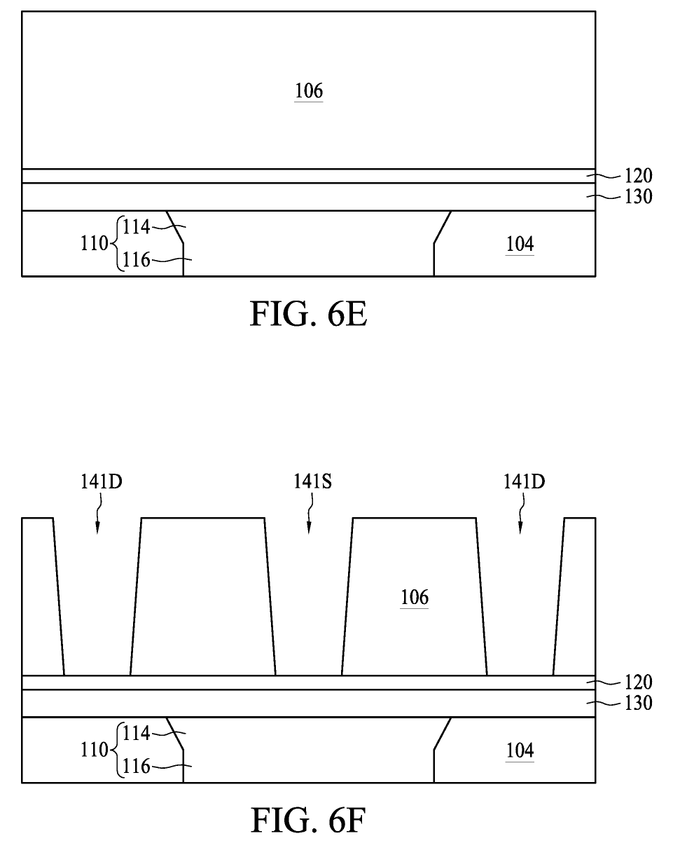

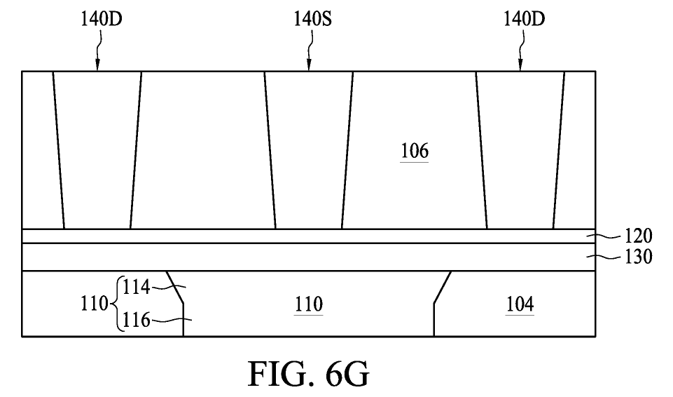

In some embodiments, a semiconductor device 100 may be formed by the method 20. FIGS. 6A-6G are schematic drawings of the semiconductor device 100 at various fabrication stages constructed according to aspects of the present disclosure in one or more embodiments.

Referring to FIG. 6A, in some embodiments, in operation 21, a dielectric structure 104 is formed over a substrate (not shown), wherein the subtrate may be referred to as a supporting structure. The substrate may include FEOL devices, MEOL elements, and a BEOL interconnect structure 102. In some embodiments, the substrate may be a part of the BEOL interconnect structure 102 (as shown in FIG. 1). In some embodiments, the dielectric structure 104 may be a part of an inter-metal dielectric (IMD) of the BEOL interconnect structure 102. In some embodiments, the dielectric structure 104 may be a single-layered structure. In other embodiments, the dielectric structure 104 may be a multi-layered structure. The dielectric structure 104 includes silicon oxide, silicon nitride, silicon oxynitride, or the like, which may be deposited by chemical vapor deposition (CVD), physical vapor deposition (PVD), atomic layer deposition (ALD), plasma-enhanced CVD (PECVD), or the like.

Still referring to FIG. 6A, in some embodiments, in operation 22, a first trench 105 is formed in the dielectric structure 104. In some embodiments, a patterned hard mask 108 is formed over the dielectric structure 104. The patterned hard mask 108 may include trenches revealing portions of the dielectric structure 104. For example, the trenches correspond to a shape of a gate structure formed in subsequent steps. After the formation of the patterned hard mask 108, an etching process is performed to remove portions of the dielectric structure 104. In some embodiments, the etching process may include dry etching, but the disclosure is not limited thereto. Accordingly, the first trench 105 is formed in the dielectric structure 104. The patterned hard mask 108 may be removed after the formation of the first trench 105. As shown in FIG. 6A, the first trench 105 has a width Wt1.

Referring to FIG. 6B, in some embodiments, in operation 23, a second trench 107 is formed over and coupled to the first trench 105. In some embodiments, portions of the dielectric structure 104 around an upper portion of the first trench 105 may be removed, thereby forming the second trench 107 over and coupled to the first trench 105. In some embodiments, the removal of the portion of the dielectric structure 104 may include an ion bombardment 109, but the disclosure is not limited thereto. As shown in FIG. 6B, a width Wt2 of the second trench 107 is greater than the width Wt1 of the first trench 105. In some embodiments, the width Wt2 of the second trench 107 increases at positions of increasing height from a width equal to the width Wt1 to a maximum width that is greater than the width Wt1 of the first trench 105. Accordingly, the second trench 107 has tapered sidewalls, as shown in FIG. 6B. In some embodiments, a slope of the sidewalls of the first trench 105 is greater than a slope of the sidewalls of the second trench 107. In some embodiments, a depth of the first trench 105 is greater than a depth of the second trench 107, but the disclosure is not limited thereto.

Referring to FIG. 6C, in some embodiments, in operation 24, a gate structure 110 is formed in the first trench 105 and the second trench 107. A material of the gate structure 110 may be similar to materials of the gate structures described above; therefore, repeated descriptions are omitted. In various embodiments, the gate structure 110 may be formed using one or more deposition processes (e.g., atomic layer deposition (ALD) processes, chemical vapor deposition (CVD) processes, plasma-enhanced chemical vapor deposition (PE-CVD) processes, or the like), and various patterning processes.

As shown in FIG. 6C, the first trench 105 and the second trench 107 are filled with the abovementioned conductive material, and a planarization is performed to remove superfluous conductive material to form the gate structure 110. Accordingly, the gate structure 110 includes a first portion 114 formed in the second trench 107, and a second portion 116 formed in the first trench 105. The first portion 114 of the gate structure 110 has a width Wg1 substantially equal to the width Wt2 of the second trench 107, and the second portion 116 of the gate structure 110 has a width Wg2 substantially equal to the width Wt1 of the first trench 105. Therefore, the width Wg1 of the first portion 114 is greater than the width Wg2 of the second portion 116. Further, the width Wg1 of the first portion 114 increases at positions of increased height.

Referring to FIG. 6D, in some embodiments, in operation 25, a gate dielectric layer 130 and a channel layer 120 are formed over the gate structure 110. A material of the gate dielectric layer 130 may be similar to materials of the gate dielectric layers described above, and repeated descriptions are omitted. In some embodiments, the gate dielectric layer 130 may be formed using one or more deposition processes (e.g., ALD processes, CVD processes, physical vapor deposition (PVD) processes, PE-CVD processes, or the like), and one or more patterning processes.

Still referring to FIG. 6D, the channel layer 120 is formed over the gate dielectric layer 130. A material of the channel layer 120 is similar to that of the channel layer 120 described above, and repeated descriptions are omitted. In some embodiments, the channel layer 120 may be formed using one or more deposition processes (e.g., ALD processes, CVD processes, physical vapor deposition (PVD) processes, PE-CVD processes, or the like), and one or more patterning processes.

In some embodiments, in operation 26, a source structure and a drain structure are formed over the channel layer 120. In some embodiments, operation 26 includes further operations. For example, referring to FIG. 6E, a dielectric structure 106 may be formed over the channel layer 120. In some embodiments, the dielectric structure 106 may include materials same as materials of the IMD in the BEOL interconnect structure 102, but the disclosure is not limited thereto. In some embodiments, the dielectric structure 106 may be a single-layered structure. In other embodiments, the dielectric structure 106 may be a multi-layered structure.

Referring to FIG. 6F, in some embodiments, the dielectric structure 106 is patterned to form trenches 141D and 141S that expose portions the channel layer 120. The trenches 141D and 141S are separated from each other. The dielectric structure 106 is exposed through sidewalls of each of the trenches 141S and 141D, and the channel layer 120 is exposed through a bottom of each of the trenches 141S and 141D.

Referring to FIG. 6G, in some embodiments, a conductive material is formed to fill the trenches 141S and 141D. In some embodiments, a barrier layer (not shown) may be formed prior to the forming of the conductive material. In some embodiments, the conductive material may include metals such as TiN, Mo, W, or Al, but the disclosure is not limited thereto. A planarization is performed to remove superfluous material, thereby forming the source structure 140S and the drain structure 140D. A semiconductor device 100 is therefore formed. As shown in FIG. 6G, in the semiconductor device 100, a height of the drain structure 140D is equal to a height of the source structure 140S. Further, a bottom of the source structure 140S and a bottom of the drain structure 140D are both coupled to or in contact with the channel layer 120, while sidewalls of the source structure 140S and sidewalls of the drain structure 140D are laterally surrounded by the dielectric structure 106.

According to the method 20, the semiconductor device 100 including the funnel-shaped gate structure 110 is formed, such that the gate-to-drain overlap is increased.

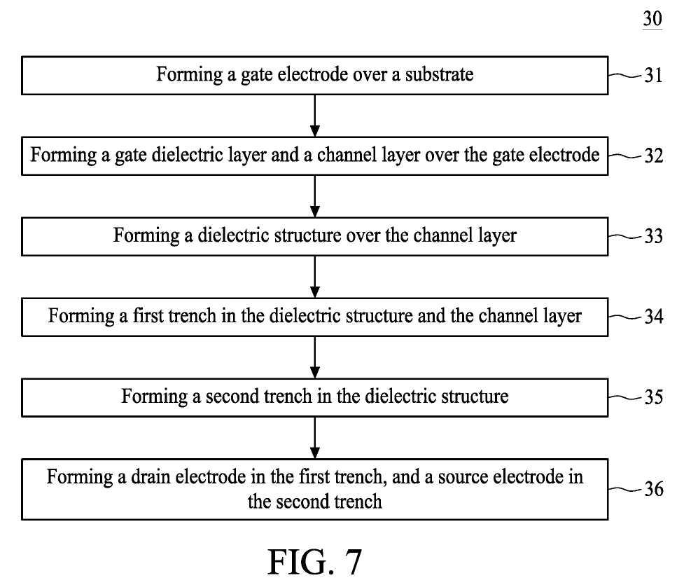

FIG. 7 is a flowchart representing a method for forming a semiconductor device 30 in accordance with aspects of the present disclosure. The method 30 includes a number of operations (31, 32, 33, 34, 35 and 36). The method 30 is further described according to one or more embodiments. It should be noted that the operations of the method 30 may be rearranged or otherwise modified within the scope of the various aspects. It should be further noted that additional processes may be provided before, during, and after the method 30, and that some other processes may be only briefly described herein. Thus, other implementations are possible within the scope of the various aspects described herein.

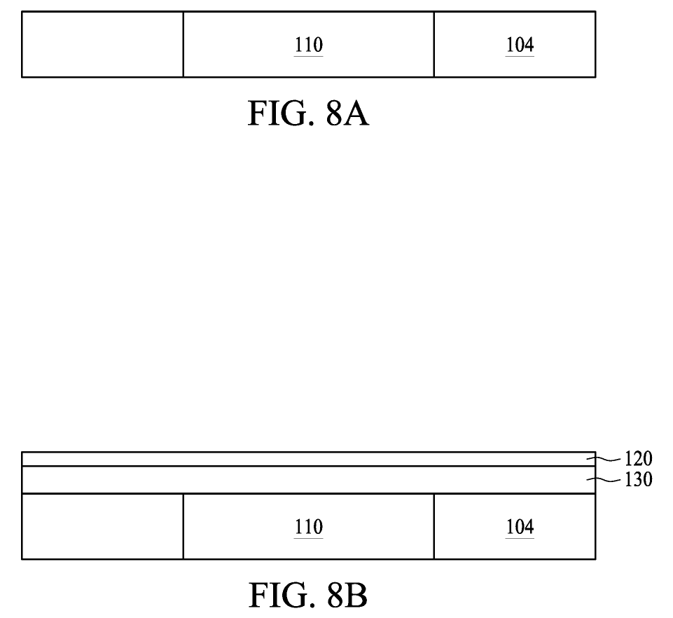

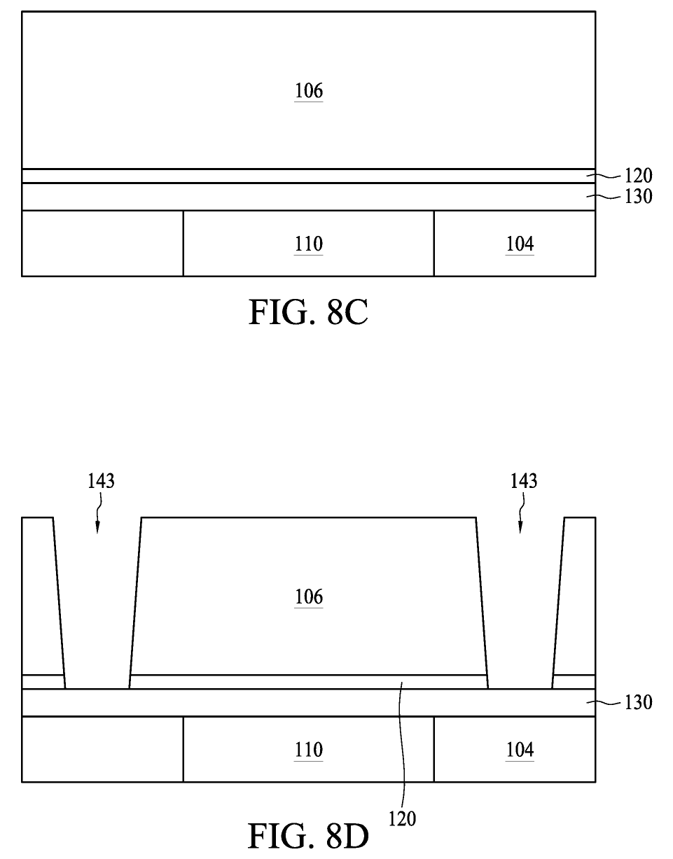

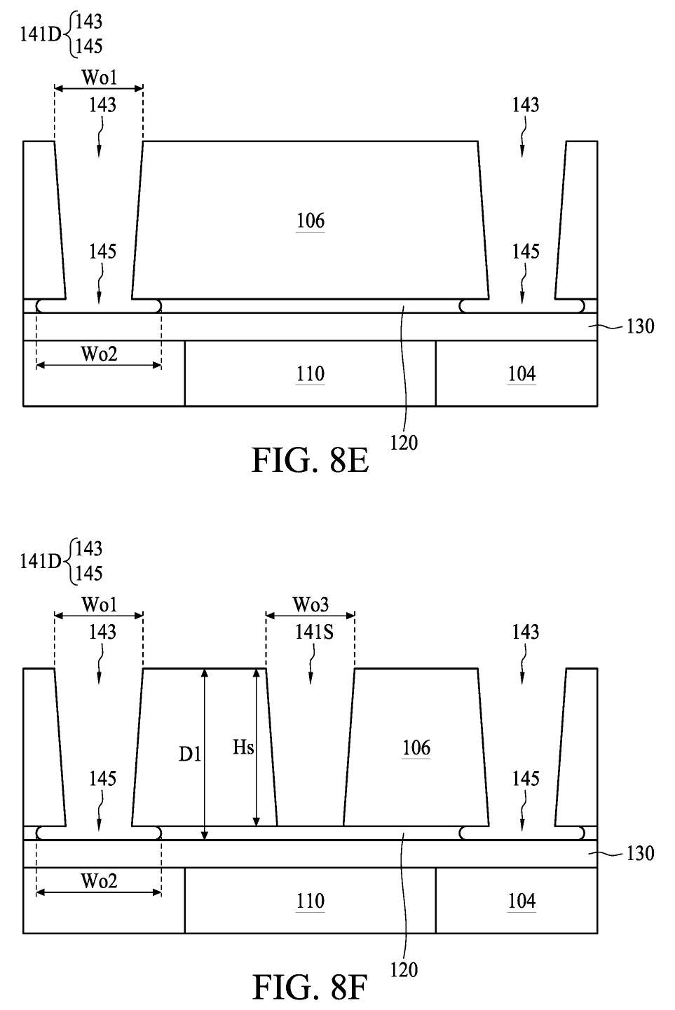

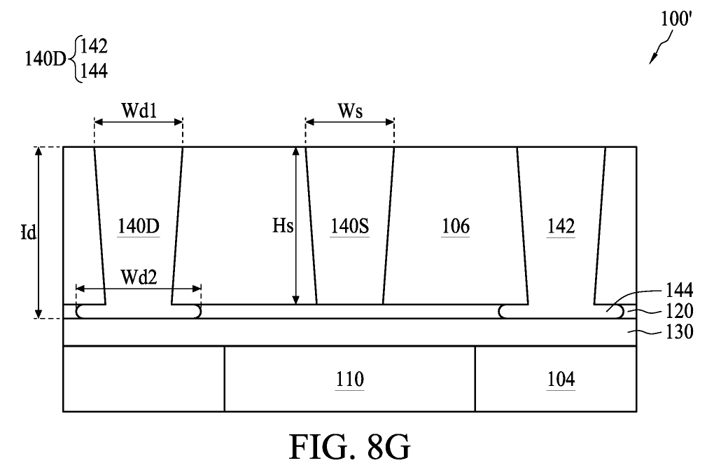

In some embodiments, a semiconductor device 100' may be formed by the method 30. FIGS. 8A-8G are schematic drawings of the semiconductor device 100' at various fabrication stages constructed according to aspects of the present disclosure in one or more embodiments.

Referring to FIG. 8A, in some embodiments, in operation 31, a gate structure 110 is formed over a substrate (not shown), wherein the substrate may be referred to as a supporting structure. As mentioned above, the substrate may include FEOL devices, MEOL elements, and a BEOL interconnect structure 102. In some embodiments, the substrate may be a part of the BEOL interconnect structure 102 (as shown in FIG. 1). In some embodiments, a dielectric structure 104 is formed over the substrate. In some embodiments, the dielectric structure 104 may be a part of an IMD of the BEOL interconnect structure 102. In some embodiments, the dielectric structure 104 may be a single-layered structure. In other embodiments, the dielectric structure 104 may be a multi-layered structure.

In operation 31, a trench may be formed in the dielectric structure 104 and filled with a conductive material. A planarization may be performed to remove superfluous conductive material, thereby forming the gate structure 110, as shown in FIG. 8A.

Referring to FIG. 8B, in some embodiments, in operation 32, a gate dielectric layer 130 and a channel layer 120 are formed over the gate structure 110. The gate dielectric layer 130 is formed on the gate structure 110, and the channel layer 120 is subsequently formed on the gate dielectric layer 130. A material of the gate dielectric layer 130 may be similar to materials of the gate dielectric layers described above, and a material of the channel layer 120 may be similar to materials of the channel layer described above; therefore, repeated descriptions are omitted.

Referring to FIG. 8C, in some embodiments, in operation 33, a dielectric structure 106 is formed over the channel layer 120. In some embodiments, the dielectric structure 106 may include materials same as materials of the IMD in the BEOL interconnect structure 102, but the disclosure is not limited thereto. As mentioned above, the dielectric structure 106 may be a single-layered structure or a multi-layered structure.

In operation 34, a first trench 141D is formed in the dielectric structure 106 and the channel layer 120. In some embodiments, the formation of the first trench 141D includes further operations. For example, a patterned hard mask (not shown) is formed over the dielectric structure 106. The patterned hard mask may include openings revealing portions of the dielectric structure 106. For example, the openings correspond to a shape of a drain structure formed in subsequent steps. After the patterned hard mask is provided, an etching process is performed to remove portions of the dielectric structure 106. In some embodiments, the etching process may include dry etching, but the disclosure is not limited thereto. Accordingly, a first opening 143 is formed in the dielectric structure 106 and the channel layer 120. As shown in FIG. 8D, in such embodiments, the dielectric structure 106 and the channel layer 120 are exposed through sidewalls of the first opening 143, while the gate dielectric layer 130 is exposed through a bottom of the first opening 143.

Referring to FIG. 8E, in some embodiments, a lateral etching is performed to remove portions of the channel layer 120 exposed through the first opening 143. An etchant having a high etching selectivity ratio of the channel layer 120 to adjacent layers (e.g., the dielectric structure 106 and the gate dielectric layer 130) may be used in the lateral etching. Accordingly, a portion of the channel layer 120 exposed through the sidewalls of the first opening 143 is removed, and a second opening 145 under and coupled to the first opening 143 is formed. The first opening 143 and the second opening 145 form the first trench 141D. It should be noted that a width Wo2 of the second opening 145 is greater than a width Wo1 of the first opening 143. In some embodiments, the dielectric structure 106 is exposed through the sidewalls of the first opening 143, and the channel layer 120 is exposed through sidewalls of the second opening 145. Further, the gate dielectric layer 130 is exposed through a bottom of the second opening 145.

Referring to FIG. 8F, in some embodiments, in operation 35, a second trench 141S separated from the first trench 141D is formed in the dielectric structure 106. In some embodiments, the formation of the second trench 141S includes further operations. For example, a protection layer may be formed over the substrate to fill the first trench 141D, though not shown. A patterned hard mask (not shown) is formed over the dielectric structure 106. The patterned hard mask may include openings revealing portions of the dielectric structure 106. For example, the openings correspond to a shape of a source structure formed in subsequent steps. After the patterned hard mask is provided, an etching process is performed to remove portions of the dielectric structure 106. In some embodiments, the etching process may include dry etching, but the disclosure is not limited thereto. Accordingly, the second trench 141S is formed in the dielectric structure 106. As shown in FIG. 8F, in such embodiments, the dielectric structure 106 is exposed through sidewalls of the second trench 141S, and the channel layer 120 is exposed through a bottom of the second trench 141S. In some embodiments, a width Wo3 of the second trench 141S is less than the width Wo2 of the second opening 145 of the first trench 141D. In some embodiments, the width Wo3 of the second trench 141S is substantially equal to the width Wo1 of the first opening 143 of the first trench 141D, but the disclosure is not limited thereto. It should be noted that a depth D1 of the first trench 141D is greater than a depth D2 of the second trench 141S.

Referring to FIG. 8G, in some embodiments, in operation 36, a source structure 140S and a drain structure 140D are formed over the gate dielectric layer 130. In some embodiments, operation 36 includes further operations. For example, a conductive material is formed to fill the first trench 141D and the second trench 141S. In some embodiments, a barrier layer (not shown) may be formed prior to the forming of the conductive material. In some embodiments, the conductive material may include metals such as TiN, Mo, W or Al, but the disclosure is not limited thereto. Still referring to FIG. 8G, the second trench 145 and the first trench 141D that includes the first opening 143 and the second opening 141S are filled with the abovementioned conductive material, and a planarization is performed to remove superfluous conductive material to form the source structure 140S in the second trench 141S and the drain structure 140D in the first trench 141D. Accordingly, the drain structure 140D includes a first portion 142 formed in the first opening 143, and a second portion 144 formed in the second opening 145. The first portion 142 of the drain structure 140D has a width Wd1 substantially equals to the width Wo1 of the first opening 143, and the second portion 144 of the drain structure 140D has a width Wd2 substantially equals to the width Wo2 of the second opening 145. Therefore, the width Wd1 of the first portion 142 is less than the width Wd2 of the second portion 144. Further, the source structure 140S has a width Ws substantially equal to the width Wo3 of the second trench 141S.

A semiconductor device 100' is therefore formed. As shown in FIG. 8G, in the semiconductor device 100', a height Hd of the drain structure 140D is greater than a height Hs of the source structure 140S. Further, a bottom of the source structure 140S is coupled to or in contact with the channel layer 120, while a bottom of the drain structure 140D is coupled to or in contact with the gate dielectric layer 130. Sidewalls of the source structure 140S are laterally surrounded by the dielectric structure 106. In contrast with the source structure 140S, sidewalls of the first portion 142 of the drain structure 140D are laterally surrounded by the dielectric structure 106, and sidewalls of the second portion 144 of the drain structure 140D are laterally surrounded by the channel layer 120.

According to the method 30, the semiconductor device 100' including a drain structure 140D with a footing (i.e., the second portion 144) is formed, such that the gate-to-drain overlap is increased.

In some embodiments, the method 20 and the method 30 can be integrated to form a semiconductor structure 100'' having the funnel-shaped gate structure 110 and the drain structure 140D with the footing.

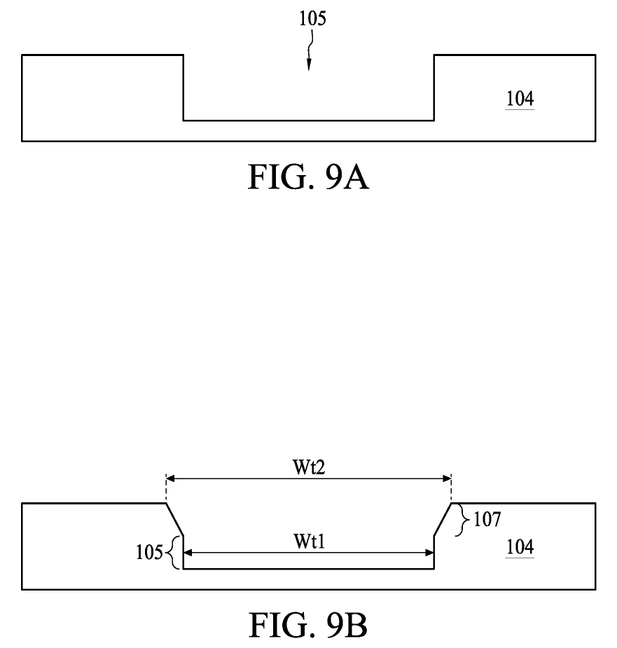

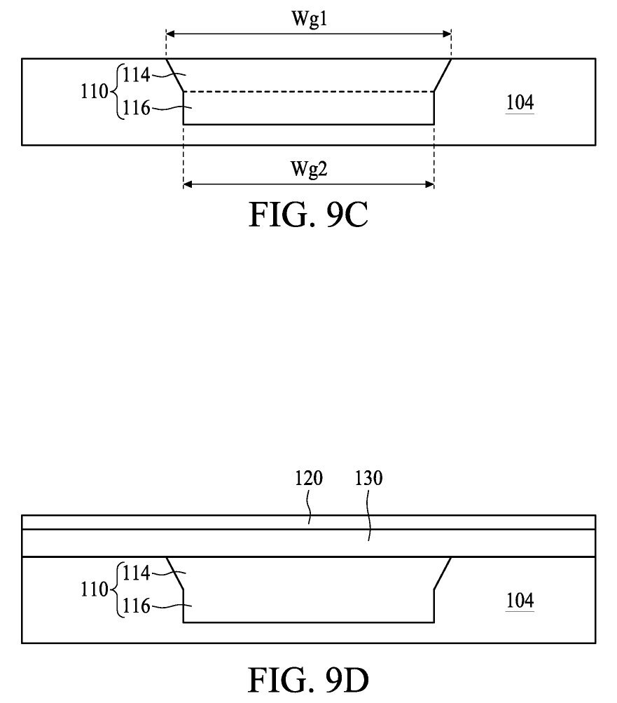

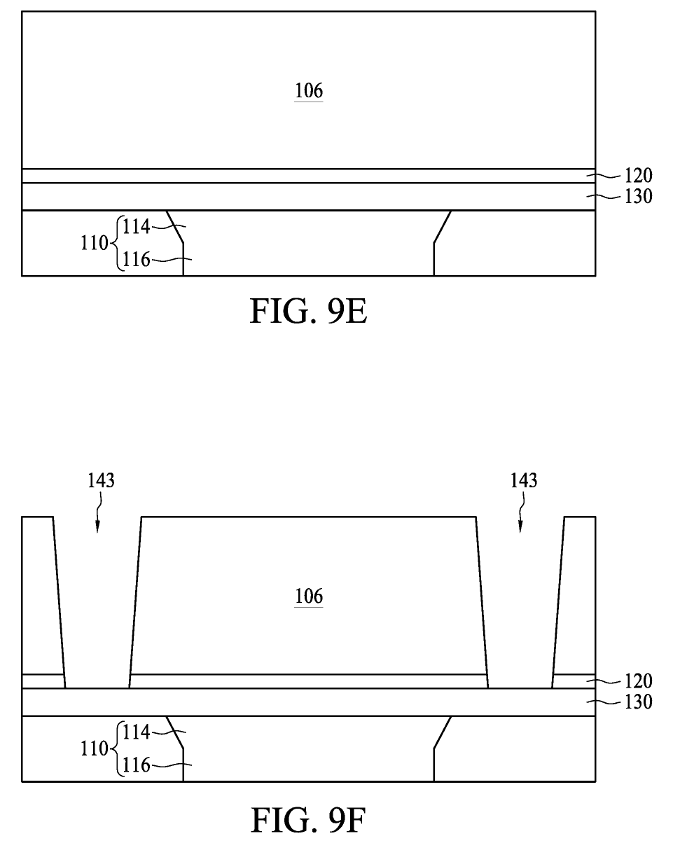

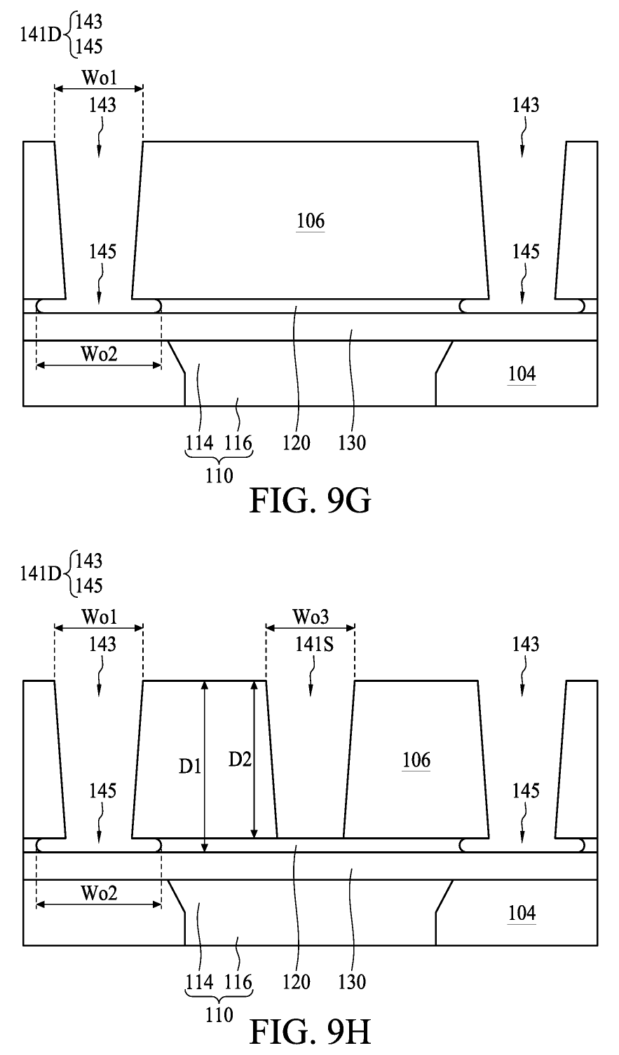

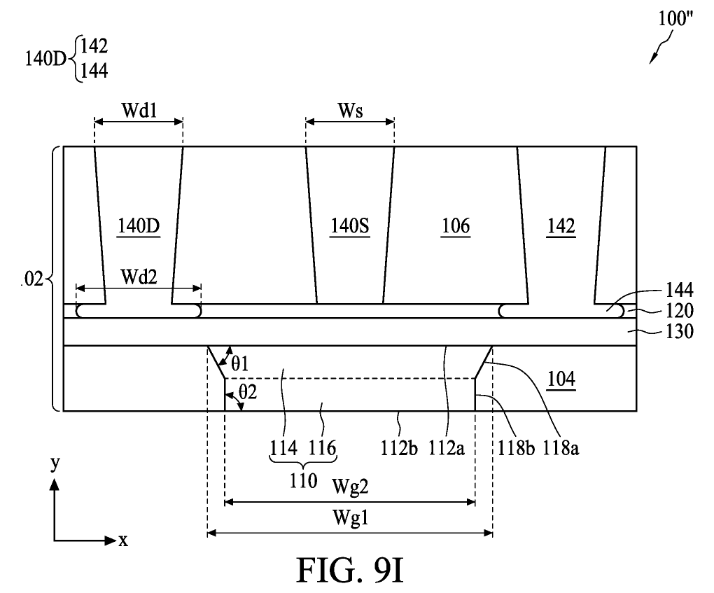

For example, in some embodiments, in operation 21, a dielectric structure 104 is formed over a substrate. In some embodiments, in operation 22, a first trench 105 (i.e., a first gate trench) is formed in the dielectric structure 104, as shown in FIG. 9A. In operation 23, a second gate trench 107 is formed over and coupled to the first gate trench 105, as shown in FIG. 9B. As mentioned above, a width Wt2 of the second gate trench 107 is greater than a width Wt1 of the first gate trench 107. In some embodiments, the width Wt2 of the second gate trench 107 increases at positions of increased height from a width equal to the width Wt1 to a maximum width that is greater than the width Wt1 of the first gate trench 105. Accordingly, the second gate trench 107 has tapered sidewalls, as shown in FIG. 9B. In some embodiments, a slope of the sidewalls of the first trench 105 is greater than a slope of the sidewalls of the second trench 107. In some embodiments, a depth of the first gate trench 105 is greater than a depth of the second gate trench 107, but the disclosure is not limited thereto.

In operation 24, a gate structure 110 is formed in the first gate trench 105 and the second gate trench 107. As mentioned above, the gate structure 110 includes a first portion 114 formed in the second gate trench 107, and a second portion 116 formed in the first gate trench 105. The first portion 114 of the gate structure 110G has a width Wg1 substantially equal to the width Wt2 of the second gate trench 107, and the second portion 116 of the gate structure 110G has a width Wg2 substantially equal to the width Wt1 of the first gate trench 105. Therefore, the width Wg1 of the first portion 114 is greater than the width Wg2 of the Details about the first portion 114 and the second portion 116 may be similar as those described above; therefore, those details are omitted for brevity.

In some embodiments, in operation 25 or in operation 32, a gate dielectric layer 130 and a channel layer 120 are sequentially formed over the gate structure 110, as shown in FIG. 9D.

In some embodiments, operation 33 may be performed after operation 25 or after operation 32. For example, a dielectric structure 106 may be formed over the channel layer 120, as shown in FIG. 9E. In operation 34, a drain trench 141D is formed in the dielectric structure 106 and the channel layer 120. In some embodiments, the formation of the drain trench 141D includes further operations. For example, as shown in FIG. 9F, a first opening 143 is formed in the dielectric structure 106 and the channel layer 120. The dielectric structure 106 and the channel layer 120 are exposed through sidewalls of the first opening 143.

In some embodiments, a lateral etching is performed to remove portions of the channel layer 120 exposed through the first opening 143. Accordingly, a second opening 145 is formed under and coupled to the first opening 143, as shown in FIG. 9G. The first opening 143 and the second opening 145 form the drain trench 141D. It should be noted that a width Wo2 of the second opening 145 is greater than a width Wo1 of the first opening 143. In some embodiments, the dielectric structure 106 is exposed through sidewalls of the first opening 143, and the channel layer 120 is exposed through sidewalls of the second opening 145. Further, the gate dielectric layer 130 is exposed through a bottom of the second opening 145.

In operation 35, a source trench 141S separated from the drain trench 141D is formed in the dielectric structure 106, as shown in FIG. 9H. The dielectric structure 106 is exposed through sidewalls of the source trench 141S, and the channel layer 120 are exposed through a bottom of the source trench 141S. In some embodiments, a width Wo3 of the source trench 141S is less than the width Wo4 of the second opening 145 of the drain trench 141D. In some embodiments, the width Wo3 of the source trench 141S is substantially equal to the width Wo1 of the first opening 143 of the drain trench 141D, but the disclosure is not limited thereto. It should be noted that a depth D1 of the drain trench 141D is greater than a depth D2 of the source trench 141S.

In operation 36, a source structure 140S and a drain structure 140D are formed over the gate dielectric layer 130, as shown in FIG. 9I. Accordingly, the drain structure 140D includes a first portion 142 formed in the first opening 143, and a second portion 144 formed in the second opening 145. The first portion 142 of the drain structure 140D has a width Wd1 substantially equal to the width Wo1 of the first opening 143, and the second portion 144 of the drain structure 140D has a width Wg2 substantially equals to the width Wo2 of the second opening 145. Therefore, the width Wd1 of the first portion 142 is less than the width Wd2 of the second portion 144. Further, the source structure 140S obtains a width Ws substantially equal to the width Wo3 of the second trench 141S.

According to the method 20 and the method 30, the semiconductor device 100'' including the funnel-shaped gate structure 110 and the drain structure 140D with the footing is formed, such that the gate-to-drain overlap is increased.

Accordingly, the present disclosure provides a semiconductor device and a method for forming the same. In some embodiments, the semiconductor device includes a gate structure having a funnel-shaped configuration that helps to increase gate-to-drain overlap. In other embodiments, the semiconductor device includes a drain structure having a footing configuration that helps to increase the gate-to-drain overlap. In still other embodiments, the semiconductor device includes both the funnel-shaped gate structure and the drain structure having the footing. It should be understood that the gate-to-drain overlap is related to a turn-on current and sub-threshold swing of a device. The increased gate-to-drain overlap improves gate control capability and an increased fringing field, thereby improving device performance. Further, gate capacitance coupling is reduced.

In some embodiments, a semiconductor device is provided. The semiconductor device includes a gate structure, a channel layer over the gate structure, a gate dielectric layer between the gate structure and the channel layer, and a source structure and a drain structure over the gate structure. A height of the source structure is different from a height of the drain structure. The gate structure has a first surface facing the source structure and the drain structure, and a second surface opposite to the first surface. A width of the first surface is greater than a width of the second surface.

In some embodiments, a method for forming a semiconductor structure is provided. The method includes following operations. A dielectric structure is formed over a substrate. A first trench is formed in the dielectric structure. The first trench has a first width. A second trench is formed over and coupled to the first trench. The second trench has a second width greater than the first width. A gate structure is formed in the first trench and the second trench. A gate dielectric layer and a channel layer are formed over the gate structure. A source structure and a drain structure are formed over the channel layer.

In some embodiments, a method for forming a semiconductor structure is provided. The method includes following operations. A gate structure is formed over a substrate. A gate dielectric layer and a channel layer are formed over the gate structure. A dielectric structure is formed over the channel layer. A first trench is formed in the dielectric structure and the channel layer. A second trench separated from the first trench is formed in the dielectric structure. A drain structure is formed in the first trench, and a source structure is formed in the second trench.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a gate structure;
a channel layer over the gate structure;
a gate dielectric layer between the gate structure and the channel layer; and
a source structure and a drain structure over the gate structure,
wherein a height of the source structure is different from a height of the drain structure,
wherein the gate structure has a first surface facing the source structure and the drain structure, and a second surface opposite to the first surface, and
wherein a width of the first surface is greater than a width of the second surface.

2. The semiconductor device of claim 1, wherein the gate structure comprises:
a first portion having the first surface; and
a second portion under and coupled to the first portion, and having the second surface,
wherein the first portion has a first sidewall with a first slope, the second portion has a second sidewall with a second slope, and the second slope is greater than the first slope.

3. The semiconductor device of claim 2, wherein the first portion has a first tangent angle formed by the first sidewall and the first surface, the second portion has a second tangent angle formed by the second sidewall and the second surface, and the first tangent angle is less than the second tangent angle.

4. The semiconductor device of claim 3, wherein the first tangent angle is less than 90 degrees, and the second tangent angle is equal to or greater than 90 degrees.

5. The semiconductor device of claim 1, wherein a bottom of the source structure is in contact with the channel layer, and a bottom of the drain structure is in contact with the gate dielectric layer.

6. The semiconductor device of claim 1, wherein the drain structure comprises:
a first portion; and
a second portion under and coupled to the first portion,
wherein a width of the second portion is greater than a width of the first portion.

7. The semiconductor device of claim 6, wherein sidewalls of the second portion are laterally surrounded by the channel layer.

8. The semiconductor device of claim 6, wherein the width of the second portion of the drain structure is greater than a width of the source structure.

9. A method for forming a semiconductor device, comprising:
forming a dielectric structure over a substrate;
forming a first trench in the dielectric structure, wherein the first trench has a first width;
forming a second trench over and coupled to the first trench, wherein the second trench has a second width greater than the first width;
forming a gate structure in the first trench and the second trench;
forming a gate dielectric layer and a channel layer over the gate structure; and
forming a source structure and a drain structure over the gate dielectric layer.

10. The method of claim 9, wherein the second trench has tapered sidewalls.

11. The method of claim 9, further comprising performing an ion bombardment to form the second trench.

12. The method of claim 9, wherein a height of the drain structure is equal to a height of the source structure.

13. The method of claim 9, wherein a height of the drain structure is greater than a height of the source structure.

14. The method of claim 9, wherein a bottom of the drain structure is coupled to the gate dielectric layer, and a bottom of the source structure is coupled to the channel layer.

15. A method for forming a semiconductor device, comprising:
forming a gate structure over a substrate;
forming a gate dielectric layer and a channel layer over the gate structure;
forming a dielectric structure over the channel layer;
forming a first trench in the dielectric structure and the channel layer;
forming a second trench separated from the first trench in the dielectric structure; and
forming a drain structure in the first trench, and forming a source structure in the second trench.

16. The method of claim 15, wherein a depth of the first trench is greater than a depth of the second trench.

17. The method of claim 15, wherein the gate dielectric layer is exposed through a bottom of the first trench, and the channel layer is exposed through a bottom of the second trench.

18. The method of claim 15, wherein the forming of the first trench comprises:
forming a first opening in the dielectric structure and the channel layer; and
laterally removing a portion of the channel layer exposed through sidewalls of the first opening to form a second opening under and coupled to the first opening,
wherein a width of the second opening is greater than a width of the first opening.

19. The method of claim 18, wherein the dielectric structure is exposed through the first opening, and the channel layer is exposed through the second opening.

20. The method of claim 15, wherein the forming of the drain structure and the source structure further comprises:
filling the first trench and the second trench with a conductive material; and
removing superfluous conductive material to form the drain structure in the first trench and the source structure in the second trench.
